(19) United States
(12) Patent Application Publication
(10) Pub. No.: US 2026/0305301 A9
(43) Pub. Date: Oct. 1, 2026

(54) HIGH TEMPERATURE METALLIZATION

(71) Applicant: 3D Glass Solutions, Inc., Albuquerque, NM (US)

(72) Inventors: Timothy A. Gort, Rio Rancho, NM (US); Jeb H. Flemming, Albuquerque, NM (US); Irma Rocio Vazquez Hernandez, Albuquerque, NM (US)

(21) Appl. No.: 19/273,472

(22) Filed: Jul. 18, 2025

Related U.S. Application Data
(60) Provisional application No. 63/680,639, filed on Aug. 8, 2024.

(51) Int. Cl. H10W 20/41; H10W 20/00; H10W 20/40

(52) U.S. Cl. CPC H10W 20/425; H10W 20/038; H10W 20/435; H10W 20/498

(57) ABSTRACT

Provided herein is a high temperature metallization structure with a refractory diffusion barrier for high-speed computing, RF, High Temperature Controls, and mmWave electronics and components.

### CROSS-REFERENCE TO RELATED APPLICATIONS

This application claims priority to U.S. Provisional Application Ser. No. 63/680,639, filed Aug. 8, 2024, the entire contents of which are incorporated herein by reference.

### STATEMENT OF FEDERALLY FUNDED RESEARCH

None.

### TECHNICAL FIELD

The present invention relates in general to the field of a method to stable, high temperature metallization structure for high-speed computing, radio frequency (RF), high temperature control, and millimeter wave (mmWave) electronics applications.

### BACKGROUND

Without limiting the scope of the disclosure, its background is described in connection with high temperature processing of electronics.

Electronics operate at higher temperature due to applications such as high-speed computing, RF, High Temperature Control, and mmWave electronics applications. These applications use conductive metallization materials such as copper, gold silver and/or other highly conductive and or refractory metals. Each of these materials have different diffusion and oxidation characteristics. Both diffusion and oxidation are time and temperature driven phenomena. As such the longer an electronic device or system is at an elevated temperature, the greater the diffusion of the electrode material into each other. To prevent this metallization, structures often use a diffusion barrier metal between the dissimilar metals.

Diffusion barriers are used to prevent the diffusion of metal atoms into the dielectric layers or into other metals. Maintaining the integrity and performance of the conductive paths improves the reliability and longevity of the device.

Conductive diffusion barrier materials are essential in the semiconductor industry to ensure the performance and reliability of electronic devices. Advances in material science and deposition techniques continue to drive the development of more effective and efficient barrier materials, enabling the progression of semiconductor technology.

However, despite the availability of the above processed, materials, manufacturing techniques and devices, a need remains for novel methods for processing electronic materials at a high temperature.

### SUMMARY

The invention provides a metallization structure that prevents or significantly reduces the diffusion of metals used in high temperature applications including: high-speed computing, radio frequency (RF), high temperature control, and millimeter wave (mmWave) electronics applications.

As embodied and broadly described herein, an aspect of the present disclosure relates to an electrode or electronic structure for high-speed computing, radio frequency (RF), high temperature control, and millimeter microwave (mmWave) electronics, comprising: a substrate having a conductor; a refractory conductive diffusion barrier or layer within the conductor that reduces or eliminates current crowding along a length and/or a skin of the conductor. In one aspect, the refractory conductive diffusion barrier or layer is between 0.05 μm and 4 μm thick. In another aspect, the conductor comprises a bend or corner that is at a 15, 20, 30, 40, 50, 60, 70, 80,or 90 degree or a path that narrows in at least a portion of the conductor. In another aspect, the refractory conductive diffusion barrier or layer comprises at least one of: Tantalum Nitride (TaN); Titanium Nitride (TiN); Tungsten Nitride (WN); Cobalt Tungsten Phosphide (CoWP), Ruthenium (Ru), or Platinum (Pt). In another aspect, the refractory conductive diffusion barrier or layer is Platinum (Pt). In another aspect, the electrode or electronic structure is selected from at least one of: copper, nickel, platinum, and gold. In another aspect, the electrode or electronic structure is copper, nickel, platinum and gold. In another aspect, the electrode or electronic structure is, in order, copper, nickel, platinum, and gold. In another aspect, the copper is between about 0.5 μm to 20 μm thick, or is 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick. In another aspect, the nickel is between about 0.5 μm to 4 μm thick, or is 0.5, 0.6, 0.7, 0.8, 0.9, 1, 2, 3, or 4 μm thick. In another aspect, the platinum is between about 0.05 μm to 4 μm thick, or is 0.05, 0.06, 0.07, 0.08, 0.09, 0.1, 0.2, 0.3, 0.4, 0.5, 0.6, 0.7, 0.8, 0.9, 1, or 2 μm thick. In another aspect, the gold is between about 0.5 μm to 5 μm thick, or is 0.5, 0.6, 0.7, 0.8, 0.9, 1, 2, 3, 4, or 5 μm thick. In another aspect, the platinum diffusion barrier layer is 0.5 μm. In another aspect, there is no diffusion of the gold across the refractory conductive diffusion barrier or layer or into a nickel layer when the electrode or electronic structure are annealed at 600° C. for 20 minutes.

As embodied and broadly described herein, an aspect of the present disclosure relates to a method of making an electrode or electronic structure for high-speed computing, radio frequency (RF), high temperature control, and millimeter microwave (mmWave) electronics, comprising: depositing a substrate having a conductor; forming a refractory conductive diffusion barrier or layer within the conductor that reduces or eliminates current crowding along a length and/or a skin of the conductor. In one aspect, the refractory conductive diffusion barrier or layer is between 0.05 μm and 4 μm thick. In another aspect, the conductor comprises a bend or corner that is at a 15, 20, 30, 40, 50, 60, 70, 80, or 90 degree or a path that narrows in a portion of the conductor. In another aspect, the refractory conductive diffusion barrier or layer comprises at least one of: Tantalum Nitride (TaN); Titanium Nitride (TiN); Tungsten Nitride (WN); Cobalt Tungsten Phosphide (CoWP), Ruthenium (Ru), or Platinum (Pt). In another aspect, the refractory conductive diffusion barrier or layer is Platinum (Pt). In another aspect, the electrode or electronic structure is selected from at least one of: copper, nickel, platinum and gold. In another aspect, the electrode or electronic structure is copper, nickel, platinum and gold. In another aspect, the electrode or electronic structure is, in order, copper, nickel, platinum, and gold. In another aspect, the copper is between about 0.5 μm to 20 μm thick, or is 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick. In another aspect, the nickel is between about 0.5 μm to 4 μm thick, or is 0.5, 0.6, 0.7, 0.8, 0.9, 1, 2, 3, or 4 μm thick. In another aspect, the platinum is between about 0.05 μm to 4 μm thick, or is 0.05, 0.06, 0.07, 0.08, 0.09, 0.1, 0.2, 0.3, 0.4, 0.5, 0.6, 0.7, 0.8, 0.9, 1, or 2 μm thick. In another aspect, the gold is between about 0.5 μm to 5 μm thick, or is 0.5, 0.6, 0.7, 0.8, 0.9, 1, 2, 3, 4, or 5 μm thick. In another aspect, the platinum diffusion barrier layer is 0.5 μm. In another aspect, there is no diffusion across the refractory conductive diffusion barrier or layer, or into a nickel layer, when the electrode or electronic structure are annealed at 600° C. for 20 minutes. In another aspect, the refractory conductive diffusion barrier or layer is formed or deposited by at least one of: Physical Vapor Deposition (PVD); Chemical Vapor Deposition (CVD), Plasma-enhanced CVD (PECVD), low-pressure CVD (LPCVD), Atomic Layer Deposition (ALD), and/or an electrochemical process.

### BRIEF DESCRIPTION OF THE DRAWINGS

For a more complete understanding of the features and advantages of the present invention, reference is now made to the detailed description of the invention along with the accompanying figures and in which:

FIG. 1 shows an image of a copper, nickel, platinum, gold electrode structure.

FIG. 2 shows an image of a copper, nickel, platinum, gold electrode structure.

FIG. 3 shows a graph of an X-ray Fluorescence (XRF) analysis of the metallization stack post 600° C. anneal for 10 min

### DETAILED DESCRIPTION

While the making and using of various aspects of the present disclosure are discussed in detail below, it should be appreciated that the present disclosure provides many applicable inventive concepts that can be embodied in a wide variety of specific contexts. The specific aspects discussed herein are merely illustrative of specific ways to make and use the disclosure and do not delimit the scope of the disclosure.

To facilitate the understanding of this disclosure, a number of terms are defined below. Terms defined herein have meanings as commonly understood by a person of ordinary skill in the areas relevant to the present disclosure. Terms such as “a”, “an” and “the” are not intended to refer to only a singular entity, but include the general class of which a specific example may be used for illustration. The terminology herein is used to describe specific aspects of the disclosure, but their usage does not delimit the disclosure, except as outlined in the claims.

In the specification, reference may be made to the spatial relationships between various components and to the spatial orientation of various aspects of components as the devices are depicted in the attached drawings. However, as will be recognized by those skilled in the art after a complete reading of the present application, the devices, members, apparatuses, etc. described herein may be positioned in any desired orientation. Thus, the use of terms such as “above,” “below,” “upper,” “lower,” or other like terms to describe a spatial relationship between various components or to describe the spatial orientation of aspects of such components should be understood to describe a relative relationship between the components or a spatial orientation of aspects of such components, respectively, as the device described herein may be oriented in any desired direction.

High-speed computing, radio frequency (RF), high temperature control, and millimeter wave (mmWave) electronics use highly conductive electrode material that range in thickness from 0.1 μm to 20 μm. mmWave refers to a range of high-frequency radio waves, typically between 24 GHz and 100 GHz, used in 5G technology. These waves offer the potential for very high-speed data transmission and ultra-low latency, but they have limited range and struggle to penetrate obstacles.

The thickness of the electrode is determined using several factors. At DC frequencies, i.e., less than 1 Hz, the electrode can use thin conductive materials. Frequencies >1 GHz need to be concerned with current crowding and RF skin effects. Current crowding and skin effects occur at high frequencies where the electrons are transmitted at near the surface or skin of the electrode. Current crowding occurs when the electric current is not uniformly distributed across a conductor, leading to higher current densities in specific regions. The skin effect is the tendency of alternating current (>1 GHz) that become distributed within a conductor such that the current density is highest near the surface of the conductor and decreases exponentially with greater depths in the conductor.

Current crowding and RF skin effects occur at sharp corners or narrow paths in the conductor and can cause the current to crowd into a smaller cross-sectional area. Variations in the material properties, with high resistivity, can lead to uneven current distribution. Current crowding and RF Skin effects can result in: increased local heating; electromigration; and reduced efficiency. The increase in localized heating is due the higher current densities, which lead to increased Joule heating, producing thermal damage. Electromigration of materials in the electrode stack occur from high current densities and can lead to the movement of atoms in the conductor, degrading the material and leading to failure. Reduced efficiency is the result if uneven current distribution can increase the overall resistance of the system, thereby reducing its electrical efficiency or higher loss. It was found herein that increased local heating, electromigration, and reduced efficiency can be mitigated by design optimization that avoids sharp corners and narrow paths in the design of conductors and uses material with uniform properties and high thermal and electrical conductivity and the prevention of material diffusion of the materials that result in the change of the uniformity of the conductor's structure. The skin depth can be calculated using the mathematical formula below.
The skin depth & is given by:

$$δ = \sqrt{\frac{2 ρ}{μ ω}}$$

where:
   ρ is the resistivity of the conductor material,
   μ is the permeability of the conductor material,
   ω is the angular frequency of the AC signal.

Even with proper electrode design and material selection the primary cause of RF losses is associated with the change of contact/electrical structure due to exposure to high temperature for prolonged periods of time. The specific time and temperature exposure that creates the change is electrical structure is due to the diffusion of one material into the other metal. FIG. 1 shows an image of a copper (100), nickel (101), platinum (102), gold (103) electrode structure. Nickel is generally used as a diffusion barrier to prevent the diffusion of gold into the copper. At processing or operational temperatures greater than 200° C., gold readily diffuses into the nickel reducing the thickness of the gold resulting in a thin cross section inducing current crowding, higher RF/mmWave losses, joules heating and potentially thermal run-away damage. Above 400° C. the diffusion of gold becomes more exponential, thereby dramatically increasing the diffusion rate exacerbating the impact of current crowding/skin effects.

Diffusion barrier materials require high electrical conductivity. To minimize resistance in the conductive path, effective barrier properties are needed to prevent diffusion of metals like copper and other materials. Thermal stability is needed to enable use of the barrier over a broad temperature range that withstands high-temperature processing steps; plus, compatibility with semiconductor processing to enable seamlessly integration in existing manufacturing processes.

Refractory conductive diffusion barrier materials include: Tantalum Nitride (TaN); Titanium Nitride (TiN), Tungsten Nitride (WN), Cobalt Tungsten Phosphide (CoWP), Ruthenium (Ru), and/or Platinum (Pt), and combinations thereof.

Tantalum Nitride (TaN) can be deposition using: physical vapor deposition (PVD), chemical vapor deposition (CVD), and/or atomic layer deposition (ALD). TaN is good barrier, adhesion layer and can be used as a thin film resistor in semiconductor fabrication used in electronic devices and systems.

Titanium Nitride (TiN) is used as a barrier and adhesion layer in semiconductor device used in electronic devices and systems. TiN can be deposition using: physical vapor deposition (PVD), chemical vapor deposition (CVD), and/or atomic layer deposition (ALD).

Tungsten Nitride (WN) has excellent barrier properties and is compatible with high-temperature processes and applications. Tungsten Nitride is primarily use in copper metallization and can be deposited using CVD and/or ALD.

Cobalt Tungsten Phosphide (CoWP) is used in as a barrier material for copper interconnects. CoWP has high conductivity, good barrier performance, and can be deposited using electrochemical processes.

Ruthenium (Ru) has a high melting point, excellent barrier properties, with good electrical conductivity. Ru is an emerging material used in advanced nodes in semiconductor manufacturing and can be deposited by: PVD, CVD, and ALD.

Platinum (Pt) can be used as a barrier material. Pt has a high melting point, excellent barrier properties, with good electrical conductivity and can be deposited by PVD, CVD and/or electrochemical processes.

Deposition techniques for use with the present invention include, e.g., Physical Vapor Deposition (PVD); Chemical Vapor Deposition (CVD). PVD involves the physical transfer of material from a target to the substrate common methods of PVD include sputtering and evaporation. CVD uses chemical reactions to deposit a solid material from a gaseous precursor. CVD is considered to have excellent conformality that is especially good for high-aspect-ratio structures. There are a number of variants of CVD including: Plasma-enhanced CVD (PECVD), low-pressure CVD (LPCVD), and/or Atomic Layer Deposition (ALD), which can also be used with the present invention.

As device geometries shrink, maintaining effective diffusion barriers becomes increasingly challenging. Innovations in material science and deposition techniques are required particularly for high temperature applications and environments.

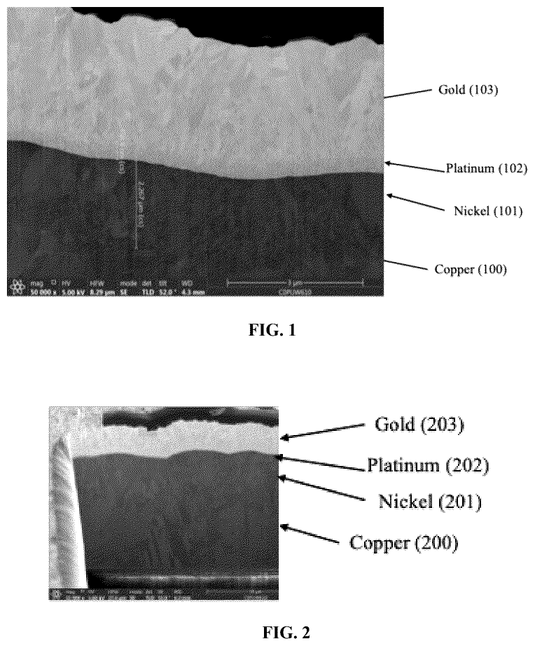

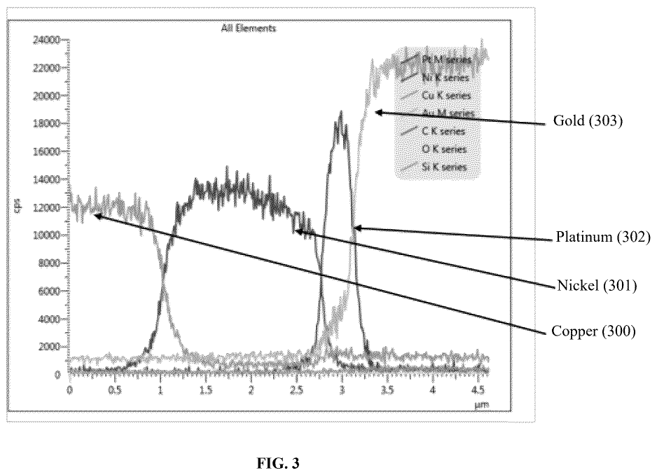

The solution is to induce a conductive refractor diffusion barrier between the gold and nickel to prevent the diffusion of the gold into and through the nickel. FIG. 2 shows an image of a one such electrode structure post 600° C. anneal. The electrode structure is copper (200), nickel (201), platinum (202), and gold (203) electrode. Where the general electrode structure used copper (200) that is between 0.5 μm to 20 μm thick, e.g., 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick; nickel (201) that is between 0.5 μm to 4 μm thick, e.g., 0.5, 0.6, 0.7, 0.8, 0.9, 1, 2, 3, or 4 μm thick; platinum (202) that is between 0.05 μm to 2 μm thick, e.g., 0.05, 0.06, 0.07, 0.08, 0.09, 0.1, 0.2, 0.3, 0.4, 0.5, 0.6, 0.7, 0.8, 0.9, 1, or 2 μm thick; and gold (203) that is between 0.5 μm to 5 μm thick, e.g., 0.5, 0.6, 0.7, 0.8, 0.9, 1, 2, 3, 4, or 5 μm thick. FIG. 3 is a graph that shows the X-ray Fluorescence (XRF) data of the electrode structure post 600° C. anneal. The data shows no diffusion of the gold at 600° C. The electrode structure is copper (300), nickel (301), platinum (302), and gold (303) electrode. One example of the electrode structure used copper (200) that is 5um thick, nickel (201) that is 0.5 μm to 4 μm um thick, platinum (202) that is 0.5 μm thick and gold (203) that is 2 μm thick. Another example of the electrode structure shown in FIG. 2 was tested to 600° C. for 20 minutes and showed no diffusion of the gold into the nickel. While the electrode structure shown in FIG. 1 shows no significant diffusion of the gold into the nickel after exposure to 600° C. for 20 minutes. The platinum can include, or be replaced with, Tantalum Nitride (TaN); Titanium Nitride (TiN), Tungsten Nitride (WN), Cobalt Tungsten Phosphide (CoWP), and/or Ruthenium (Ru), and have a thickness of between 0.05 μm to 2 μm thick, e.g., 0.05, 0.06, 0.07, 0.08, 0.09, 0.1, 0.2, 0.3, 0.4, 0.5, 0.6, 0.7, 0.8, 0.9, 1, or 2 μm thick, and combinations thereof.

The skilled artisan will recognize that the temperature may vary depending on the material used from the thickness of the encapsulation/passivation layer identified as element 103, can vary 1, 2, 3, 4, 5, 6, 7, 8, 9, 10, 11, 12, 13, 14, or 15%.

It is contemplated that any aspects of the disclosure discussed in this specification can be implemented with respect to any method, kit, reagent, or composition of the disclosure, and vice versa. Furthermore, compositions of the disclosure can be used to achieve methods of the disclosure.

It will be understood that particular aspects described herein are shown by way of illustration and not as limitations of the disclosure. The principal features of this disclosure can be employed in various aspects without departing from the scope of the disclosure. Those skilled in the art will recognize, or be able to ascertain using no more than routine experimentation, numerous equivalents to the specific procedures described herein. Such equivalents are considered to be within the scope of this disclosure and are covered by the claims.

All publications and patent applications mentioned in the specification are indicative of the level of skill of those skilled in the art to which this disclosure pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In aspects of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), propertie(s), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

Additionally, the section headings herein are provided for consistency with the suggestions under 37 CFR 1.77 or otherwise to provide organizational cues. These headings shall not limit or characterize the disclosure(s) set out in any claims that may issue from this disclosure. Specifically, and by way of example, although the headings refer to a “Field of Invention,” such claims should not be limited by the language under this heading to describe the so-called technical field. Further, a description of technology in the “Background” section is not to be construed as an admission that technology is prior art to any disclosure(s) in this disclosure. Neither is the “Summary” to be considered a characterization of the disclosure(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure but should not be constrained by the headings set forth herein.

All of the compositions and/or methods disclosed and claimed herein can be made and executed without undue experimentation in light of the present disclosure. While the compositions and methods of this disclosure have been described in terms of preferred aspects, it will be apparent to those of skill in the art that variations may be applied to the compositions and/or methods and in the steps or in the sequence of steps of the method described herein without departing from the concept, spirit and scope of the disclosure. All such similar substitutes and modifications apparent to those skilled in the art are deemed to be within the spirit, scope and concept of the disclosure as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

What is claimed is:

1. An electrode or electronic structure for high-speed computing, radio frequency (RF), high temperature control, and millimeter microwave (mmWave) electronics, comprising:
a substrate having a conductor;
a refractory conductive diffusion barrier within the conductor that reduces or eliminates current crowding along a length and/or a skin of the conductor.

2. The electrode or electronic structure of claim 1, wherein the refractory conductive diffusion barrier is between 0.05 μm and 4 μm thick.

3. The electrode or electronic structure of claim 1, wherein the conductor comprises a bend or corner that is at a 15, 20, 30, 40, 50, 60, 70, 80, or 90 degree or a path that narrows in at least a portion of the conductor.

4. The electrode or electronic structure of claim 1, wherein the refractory conductive diffusion barrier comprises at least one of: Tantalum Nitride (TaN); Titanium Nitride (TiN);
Tungsten Nitride (WN); Cobalt Tungsten Phosphide (CoWP), Ruthenium (Ru), or Platinum (Pt).

5. The electrode or electronic structure of claim 1, wherein the refractory conductive diffusion barrier is Platinum (Pt).

6. The electrode or electronic structure of claim 1, wherein the electrode or electronic structure is selected from at least one of: copper, nickel, platinum, and gold.

7. The electrode or electronic structure of claim 1, wherein the electrode or electronic structure is copper, nickel, platinum and gold.

8. The electrode or electronic structure of claim 1, wherein the electrode or electronic structure is, in order, copper, nickel, platinum, and gold.

9. The electrode or electronic structure of claim 7, wherein the copper is between about 0.5 μm to 20 μm thick, or is 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick.

10. The electrode or electronic structure of claim 7, wherein the nickel is between about 0.5 μm to 4 μm thick, or is 0.5, 0.6, 0.7, 0.8, 0.9, 1, 2, 3, or 4 μm thick.

11. The electrode or electronic structure of claim 7, wherein the platinum is between about 0.05 μm to 4 μm thick, or is 0.05, 0.06, 0.07, 0.08, 0.09, 0.1, 0.2, 0.3, 0.4, 0.5, 0.6, 0.7, 0.8, 0.9, 1, or 2 μm thick.

12. The electrode or electronic structure of claim 7, wherein the gold is between about 0.5 μm to 5 μm thick, or is 0.5, 0.6, 0.7, 0.8, 0.9, 1, 2, 3, 4, or 5 μm thick.

13. The electrode or electronic structure of claim 11, wherein the refractory conductive diffusion barrier is platinum and is about 0.5 μm.

14. The electrode or electronic structure of claim 1, wherein there is no diffusion of the gold across the refractory conductive diffusion barrier or into a nickel layer when the electrode or electronic structure are annealed at 600° C. for 20 minutes.

15. A method of making an electrode or electronic structure for high-speed computing, radio frequency (RF), high temperature control, and millimeter microwave (mmWave) electronics, comprising:
depositing a substrate having a conductor;
forming a refractory conductive diffusion barrier within the conductor that reduces or eliminates current crowding along a length and/or a skin of the conductor.

16. The method of claim 15, wherein the refractory conductive diffusion layer is between 0.05 μm and 4 μm thick.

17. The method of claim 15, wherein the conductor comprises a bend or corner that is at a 15, 20, 30, 40, 50, 60, 70, 80, or 90 degree or a path that narrows in a portion of the conductor.

18. The method of claim 15, wherein the refractory conductive diffusion barrier comprises at least one of: Tantalum Nitride (TaN); Titanium Nitride (TiN); Tungsten Nitride (WN);
Cobalt Tungsten Phosphide (CoWP), Ruthenium (Ru), or Platinum (Pt).

19. The method of claim 15, wherein the refractory conductive diffusion barrier is Platinum (Pt).

20. The method of claim 15, wherein the electrode or electronic structure is selected from at least one of: copper, nickel, platinum and gold.

21. The method of claim 15, wherein the electrode or electronic structure is copper, nickel, platinum and gold.

22. The method of claim 15, wherein the electrode or electronic structure is, in order, copper, nickel, platinum, and gold.

23. The method of claim 21, wherein the copper is between about 0.5 μm to 20 μm thick, or is 0.5, 0.6, 0.7, 0.8, 0.9, 1, 2, 3, 4, 5, 6, 7, 8, 9, 10, 11, 12, 13, 14, 15, 16, 17, 18, 19, or 20 μm thick.

24. The method of claim 21, wherein the nickel is between about 0.5 μm to 4 μm thick, or is 0.5, 0.6, 0.7, 0.8, 0.9, 1, 2, 3, or 4 μm thick.

25. The method of claim 21, wherein the platinum is between about 0.05 μm to 4 μm thick, or is 0.05, 0.06, 0.07, 0.08, 0.09, 0.1, 0.2, 0.3, 0.4, 0.5, 0.6, 0.7, 0.8, 0.9, 1, or 2 μm thick.

26. The method of claim 21, wherein the gold is between about 0.5 μm to 5 μm thick, or is 0.5, 0.6, 0.7, 0.8, 0.9, 1, 2, 3, 4, or 5 μm thick.

27. The method of claim 21, wherein the platinum diffusion barrier is 0.5 μm.

28. The method of claim 15, wherein there is no diffusion across the refractory conductive diffusion layer when the electrode or electronic structure are annealed at 600° C. for 20 minutes.

29. The method of claim 15, wherein the refractory conductive diffusion barrier is formed or deposited by at least one of: Physical Vapor Deposition (PVD); Chemical Vapor Deposition (CVD), Plasma-enhanced CVD (PECVD), low-pressure CVD (LPCVD), Atomic Layer Deposition (ALD), and/or an electrochemical process.
